(19) United States
(12) Patent Application Publication
(10) Pub. No.: US 2026/0068302 A1
(43) Pub. Date: Mar. 5, 2026

(54) SEMICONDUCTOR DEVICE AND METHOD OF MANUFACTURING THE SEMICONDUCTOR DEVICE

(71) Applicant: Samsung Electronics Co., Ltd., Suwon-si (KR)

(72) Inventors: Eunji YANG, Suwon-si (KR); Changhyun KIM, Suwon-si (KR)

(73) Assignee: Samsung Electronics Co., Ltd., Suwon-si (KR)

(21) Appl. No.: 19/238,977

(22) Filed: Jun. 16, 2025

(30) Foreign Application Priority Data
Aug. 30, 2024 (KR) 10-2024-0117886

(51) Int. Cl. H10D 84/85; H10D 84/01; H10D 84/02

(52) U.S. Cl. CPC H10D 84/851; H10D 84/0167; H10D 84/0186; H10D 84/02

(57) ABSTRACT

A semiconductor device may include a first gate stack, a second gate stack, and a bridge. The first gate stack may include a first channel layer and a plurality of first gate electrodes provided respectively on an upper portion of the first channel layer and a lower portion of the first channel layer. The second gate stack may include a second channel layer and a plurality of second gate electrodes provided respectively on an upper portion of the second channel layer and a lower portion of the second channel layer. The bridge may connect the first gate stack and the second gate stack to each other.

### CROSS-REFERENCE TO RELATED APPLICATION

This application is based on and claims priority under 35 USC § 119 to Korean Patent Application No. 10-2024-0117886, filed on Aug. 30, 2024, in the Korean Intellectual Property Office, the disclosure of which is incorporated by reference herein in its entirety.

### BACKGROUND

### 1. Field

The disclosure relates to a semiconductor device and a method of manufacturing the semiconductor device.

### 2. Description of the Related Art

As semiconductor processes become more miniaturized, transistor sizes decrease, and the area where a gate electrode and a channel meet becomes smaller, which may lead to issues caused by short channel effects. The gate-all-around (GAA) structure is attracting attention as a way to reduce short channel effects and improve gate control. Due to their excellent scaling properties, transition metal dichalcogenide (TMD) materials may be advantageous for implementing multi-bridge channel field-effect transistors (MBCFETs) with GAA structures.

However, it may be difficult to apply existing silicon-based processes to TMD materials, and damage to TMD materials may occur during the processes. Therefore, process development may be needed to manufacture TMD MBCFETs while maintaining the quality of TMD materials.

### SUMMARY

Provided is a semiconductor device including a TMD material and a method of manufacturing a semiconductor device.

Additional aspects will be set forth in part in the description which follows and, in part, will be apparent from the description, or may be learned by practice of the presented embodiments of the disclosure.

According to an example embodiment of the disclosure, a semiconductor device may include a first gate stack comprising a first channel layer and a plurality of first gate electrodes, the plurality of first gate electrodes being provided respectively on an upper portion of the first channel layer and a lower portion of the first channel layer; a second gate stack comprising a second channel layer and a plurality of second gate electrodes, the plurality of second gate electrodes being provided respectively on an upper portion of the second channel layer and a lower portion of the second channel layer; and a bridge connecting the first gate stack and the second gate stack.

In some embodiments, the first gate stack and the second gate stack may have a symmetric structure with respect to the bridge.

In some embodiments, the first gate stack and the second gate stack may not have a symmetric structure with respect to the bridge.

In some embodiments, the bridge may connect the plurality of first gate electrodes and the plurality of second gate electrodes to each other.

In some embodiments, the bridge may include TiN.

In some embodiments, the semiconductor device may further include a source electrode on a first side of the first gate stack and the second gate stack, and a drain electrode on a second side of the first gate stack and the second gate stack.

In some embodiments, the semiconductor device may further include a gate insulating layer. The gate insulating layer may surround the first channel layer and the plurality of first gate electrodes. The gate insulating layer may surround the second channel layer and the plurality of second gate electrodes.

In some embodiments, the gate insulating layer may include a high-k material.

In some embodiments, the gate insulating layer may include at least one of aluminum oxide, hafnium oxide, zirconium oxide, or lanthanum oxide.

In some embodiments, the first channel layer and the second channel layer may each independently include a transition metal dichalcogenide (TMD) material or an oxide semiconductor.

In some embodiments, at least one of the first channel layer and the second channel layer may include the TMD material, and the TMD material may include at least one of MoS₂, WSe₂, MoSe₂, and WS₂.

In some embodiments, at least one of the first channel layer and the second channel layer may include the oxide semiconductor, and the oxide semiconductor may include indium-gallium-zinc oxide (IGZO) or Indium Tin Oxide (ITO).

In some embodiments, the plurality of first gate electrodes and the plurality of second gate electrodes may include TiN.

In some embodiments, the first gate stack and the second gate stack may be in an N-channel Metal-Oxide-Semiconductor (NMOS) transistor or a P-channel Metal-Oxide-Semiconductor (PMOS) transistor.

According to an example embodiment of the disclosure, a method of manufacturing a semiconductor device may include forming a first gate stack and a second gate stack on a substrate, the first gate stack including a first channel layer and a plurality of first gate electrodes provided respectively on an upper portion of the first channel layer and a lower portion of the first channel layer, and the second gate stack including a second channel layer and a plurality of second gate electrodes provided respectively on an upper portion of the second channel layer and a lower portion of the second channel layer; forming a via between the first gate stack and the second gate stack; and forming a bridge connecting the first gate stack and the second gate stack to the via.

In some embodiments, the first gate stack and the second gate stack may be symmetric with respect to the bridge.

In some embodiments, the bridge may connect the plurality of first gate electrodes and the plurality of second gate electrodes.

In some embodiments, the bridge may include TiN.

In some embodiments, the method may further include forming a gate insulating layer on the substrate. The gate insulating layer may surround the first channel layer and the plurality of first gate electrodes, and the gate insulating layer may surround the second channel layer and the plurality of second gate electrodes.

In some embodiments, the first channel layer and the second channel layer may each independently include a transition metal dichalcogenide (TMD) material or an oxide semiconductor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a semiconductor device according to an embodiment,

FIG. 2 is a cross-sectional view taken along line A-A′ of FIG. 1,

FIG. 3 is a cross-sectional view taken along line B-B′ of FIG. 1,

FIG. 4 is a cross-sectional view taken along line C-C′ of FIG. 1,

FIG. 5 is a cross-sectional view taken along line D-D′ of FIG. 1,

FIGS. 6A to 14B are drawings for explaining a method for manufacturing a semiconductor device, according to an embodiment,

FIG. 15 is a schematic block diagram of a display driver integrated circuit (DDI) and a display device including the DDI, according to an embodiment,

FIG. 16 is a block diagram of an electronic system including a semiconductor device according to an embodiment,

FIG. 17 is a block diagram of an electronic system including a semiconductor device according to an embodiment, and

FIG. 18 is a circuit diagram of an inverter according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, the semiconductor device and the method of manufacturing the semiconductor device according to various embodiments are described in detail with reference to the attached drawings. In the drawings below, the same reference numerals refer to the same components, and the size of each component in the drawings may be exaggerated for clarity and convenience of explanation. In addition, the embodiments described below are merely non-limiting examples, and various modifications are possible from these embodiments.

Hereinafter, terms “upper” or “on” may refer to something directly on top or indirectly placed above through non-contact. Singular expressions include plural expressions unless the context clearly indicates otherwise. Additionally, when an element is said to “include” a component, this does not mean that it excludes other components, but rather that it may include other components, unless otherwise specifically stated.

The use of the term “above” and similar referential terms may refer to both the singular and the plural. Unless the operations of a method are explicitly described in a specific order or to the contrary, these operations may be performed in any suitable order and are not necessarily limited to the order described.

The connections or lack of connections between the lines depicted in the drawings are merely illustrative of functional connections and/or physical or circuit connections, and may be represented in an actual device as alternative or additional various functional connections, physical connections, or circuit connections.

Any use of examples or example terms is intended merely to elaborate technical concepts and is not intended to limit the scope of the disclosure unless otherwise defined by the claims.

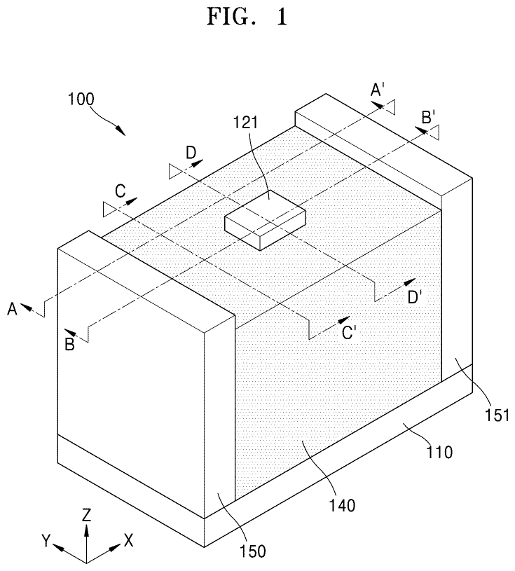

FIG. 1 is a perspective view illustrating a semiconductor device according to an embodiment.

Referring to FIG. 1, a semiconductor device 100 may include a source electrode 150 and a drain electrode 151 provided on a substrate 110 and spaced apart in a direction parallel to the surface of the substrate 110, a bridge 121 provided between the source electrode 150 and the drain electrode 151, and a gate insulating layer 140 filling the space between the source electrode 150 and the drain electrode 151.

The substrate 110 may be an insulating substrate, or may be a semiconductor substrate with an insulating layer formed on the surface. For example, the substrate 110 may include silicon (Si), such as single crystal silicon, polycrystalline silicon, or amorphous silicon. The substrate 110 may include a group IV semiconductor such as germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). The substrate 110 may be based on a silicon bulk substrate or may be based on a Silicon On Insulator (SOI) substrate. The substrate 110 is not limited to a bulk or SOI substrate, but may also be a substrate based on an epitaxial wafer, a polished wafer, an annealed wafer, and the like.

The substrate 110 may include a conductive region, such as a well doped with impurities, or various structures doped with impurities. Additionally, the substrate 110 may be configured as a p-type substrate or an n-type substrate depending on the type of impurity ion being doped.

The source electrode 150 and the drain electrode 151 may include, but are not limited to, highly electrically conductive metal materials such as Ag, Au, Pt, or Cu.

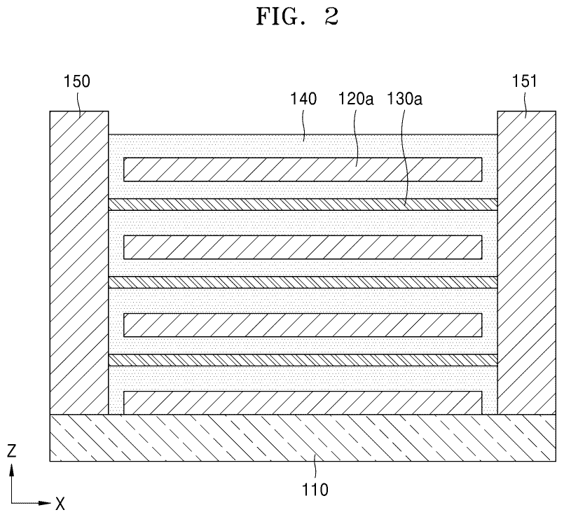

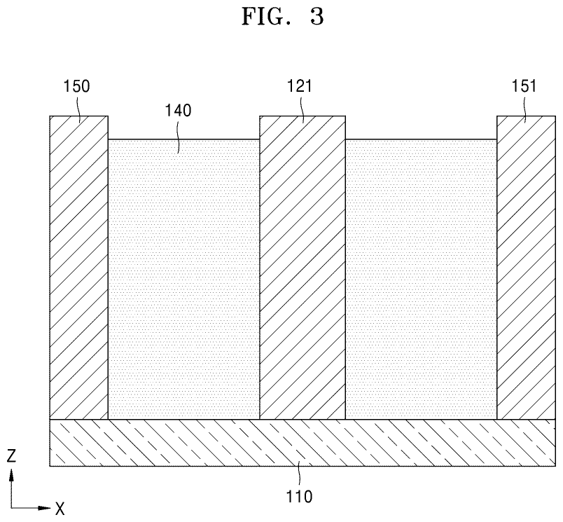

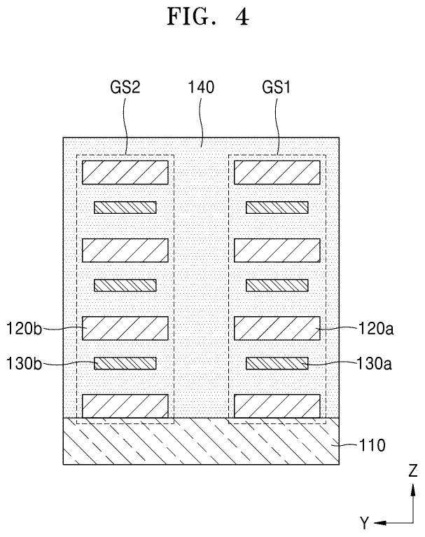

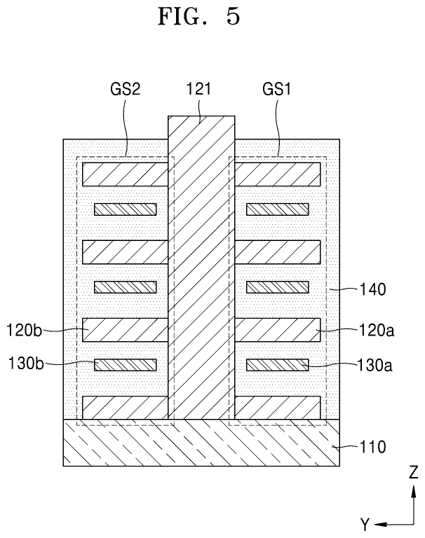

FIG. 2 is a cross-sectional view taken along line A-A′ of FIG. 1, FIG. 3 is a cross-sectional view taken along line B-B′ of FIG. 1, FIG. 4 is a cross-sectional view taken along line C-C′ of FIG. 1, and FIG. 5 is a cross-sectional view taken along line D-D′ of FIG. 1.

Referring to FIGS. 2 to 5, the semiconductor device 100 may include a first gate stack GS1 including a plurality of first channel layers 130a, and a plurality of first gate electrodes 120a respectively provided on upper and lower portions of the plurality of first channel layers 130a; a second gate stack GS2 including a plurality of second channel layers 130b, and a plurality of second gate electrodes 120b respectively provided on upper and lower portions of the plurality of second channel layers 130b; and a bridge 121 connecting the first gate stack GS1 and the second gate stack GS2.

Each of the plurality of first gate electrodes 120a may be provided spaced apart in a direction perpendicular to the surface of the substrate 110. Each of the plurality of second gate electrodes 120b may be provided spaced apart in a direction perpendicular to the surface of the substrate 110.

The first gate electrode 120a may include a conductive material. The first gate electrode 120a may include, for example, a metal, a metal nitride, a metal oxide, polysilicon, or the like. As a specific example, the first gate electrode 120a may include at least one of TiN, W, TaN, WN, NbN, Mo, Ru, Ir, RuO, IrO, and highly doped polysilicon. The first gate electrode 120a may include metal carbide or a two-dimensional conductive material.

The second gate electrode 120b may include a conductive material. The second gate electrode 120b may include, for example, a metal, a metal nitride, a metal oxide, polysilicon, or the like. As a specific example, the second gate electrode 120b may include at least one of TiN, W, TaN, WN, NbN, Mo, Ru, Ir, RuO, IrO, and highly doped polysilicon. The second gate electrode 120b may include metal carbide or a two-dimensional conductive material.

The first channel layer 130a may be provided between the plurality of first gate electrodes 120a. The first channel layer 130a may include, for example, Transition Metal Dichalcogenide (TMD). TMD may be represented, for example, by Formula MX2, where M represents a transition metal and X represents a chalcogen element. For example, M may be Mo, W, Nb, V, Ta, Ti, Zr, Hf, Tc, Re, etc., and X may be S, Se, Te, etc. So, for example, TMD may include MoS₂, WSe₂, MoSe₂, or WS₂.

The first channel layer 130a may include, for example, an oxide semiconductor. The oxide semiconductor may include, for example, IGZO or ITO.

The second channel layer 130b may be provided between the plurality of second gate electrodes 120b. The second channel layer 130b may be provided to be surrounded by a second gate electrode 120b and a third gate electrode 120c.

The second channel layer 130b may include, for example, Transition Metal Dichalcogenide (TMD). TMD may be represented, for example, by Formula MX2, where M represents a transition metal and X represents a chalcogen element. For example, M may be Mo, W, Nb, V, Ta, Ti, Zr, Hf, Tc, Re, etc., and X may be S, Se, Te, etc. The TMD may include, for example, MoS₂, WSe₂, MoSe₂, or WS₂. However, it is not limited to these and other materials may be used as TMD materials.

The second channel layer 130b may include, for example, an oxide semiconductor. The oxide semiconductor may include, for example, indium-gallium-zinc oxide (IGZO) or Indium Tin Oxide (ITO).

The bridge 121 connecting the first gate stack GS1 and the second gate stack GS2 may include the same material as the first gate electrode 120a and the second gate electrode 120b. The bridge 121 may include, for example, TiN. The bridge 121 may be referred to as a third gate electrode.

As illustrated in FIG. 5, the first gate stack GS1 and the second gate stack GS2 may have a symmetric structure with respect to the bridge 121. However, example embodiments are not limited thereto. In some embodiments, the first gate stack GS1 and the second gate stack GS2 may not have a symmetric structure with respect to the bridge 121.

The gate insulating layer 140 may be provided to surround the first gate electrode 120a and the second gate electrode 120b. The gate insulating layer 140 may be provided to surround the first channel layer 130a and the second channel layer 130b.

The gate insulating layer 140 insulates between the first gate electrode 120a and the first channel layer 130a, and may limit and/or suppress leakage current. The gate insulating layer 140 insulates between the second gate electrode 120b and the second channel layer 130b, and may limit and/or suppress leakage current.

The gate insulating layer 140 may include a high-k material. For example, the gate insulating layer 140 may include aluminum oxide, hafnium oxide, zirconium oxide, zirconium hafnium oxide, or lanthanum oxide. However, it is not limited to these.

The first gate stack GS1 may be an NMOS transistor or a PMOS transistor, and the second gate stack GS2 may be a transistor having a different type of conductivity than the first gate stack GS1. That is, the first gate stack GS1 may be an NMOS transistor, and the second gate stack GS2 may be a PMOS transistor. Alternatively, the first gate stack GS1 may be a PMOS transistor and the second gate stack GS2 may be an NMOS transistor.

In this case, the semiconductor device 100 may be a Complementary Metal-Oxide Semiconductor (CMOS) device. A CMOS device typically may include both NMOS and PMOS transistors. An example of a CMOS device is a CMOS inverter. A CMOS inverter is a circuit that operates so that the output and input are in opposite states. In other words, a CMOS inverter is a device that outputs 1 when 0 is input, and outputs 0 when 1 is input.

Meanwhile, it is not limited to this, and the first gate stack GS1 may be an NMOS transistor or a PMOS transistor, and the second gate stack GS2 may be a transistor with the same type of conductivity as the first gate stack GS1.

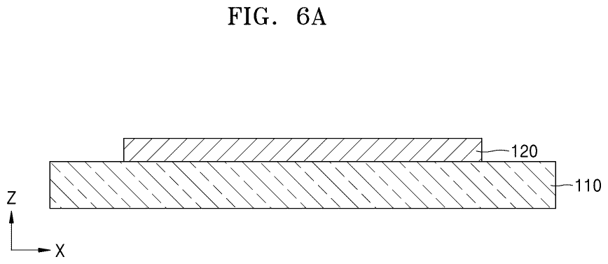

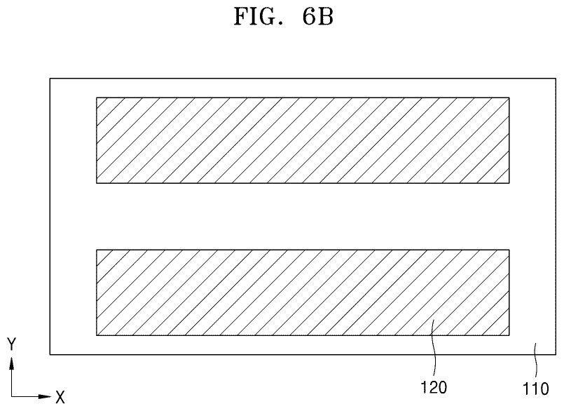

FIGS. 6A to 14B are drawings illustrating a method of manufacturing a semiconductor device according to an embodiment.

The method of manufacturing a semiconductor device according to an embodiment illustrates the method of manufacturing a semiconductor device 100 of FIG. 1. In explaining FIGS. 6A to 14B, overlapping content with FIGS. 1 to 5 is omitted.

The method of manufacturing a semiconductor device according to an embodiment is described by showing the manufacturing process operations together for the xz plane view and the xy plane view. FIGS. 6A, 7A, 8A, 9A, 10A, 11A, 12A, 13A, and 14A show the xz plane view. FIGS. 6B, 7B, 8B, 9B, 10B, 11B, 12B, 13B, and 14B show the xy plane view.

Referring to FIGS. 6A and 6B, a plurality of gate electrodes 120 may be formed spaced apart from each other on a substrate 110. The plurality of gate electrodes 120 may form a first gate stack GS1 of FIG. 1 and a second gate stack GS2 of FIG. 1, respectively. The substrate 110 may be the substrate 110 described in FIG. 1. The gate electrode 120 may include, for example, TiN.

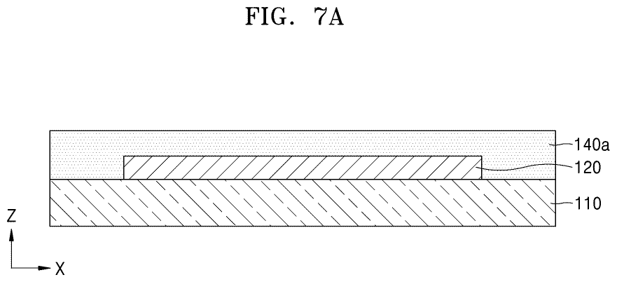

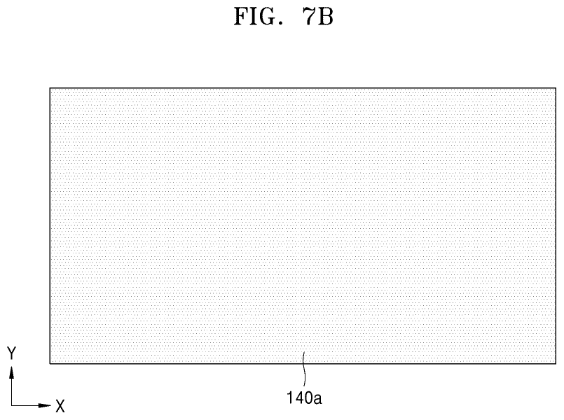

Referring to FIGS. 7A and 7B, a first gate insulating layer 140a surrounding a plurality of gate electrodes 120 may be formed. The first gate insulating layer 140a may be formed by Chemical Vapor Deposition (CVD), Metal Organic Chemical Vapor Deposition (MOCVD), or Atomic Layer Deposition (ALD) processes.

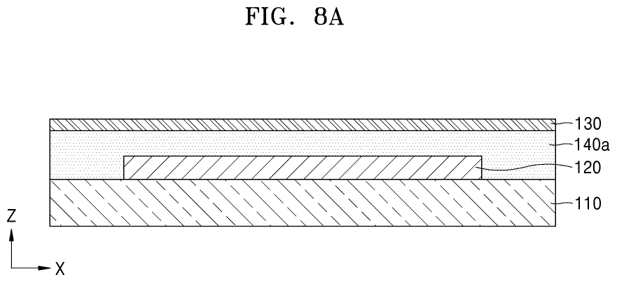

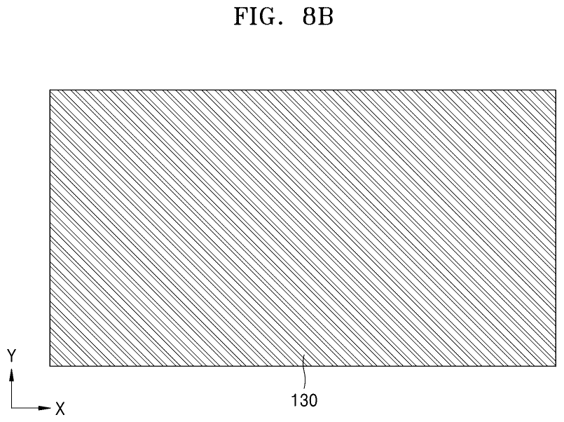

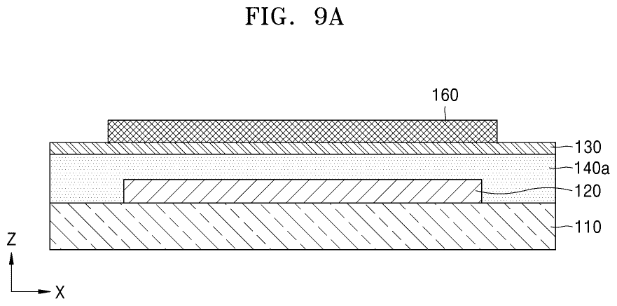

Referring to FIGS. 8A and 8B, a channel layer 130 may be formed on the first gate insulating layer 140a. The channel layer 130 may be formed by CVD, MOCVD or ALD processes.

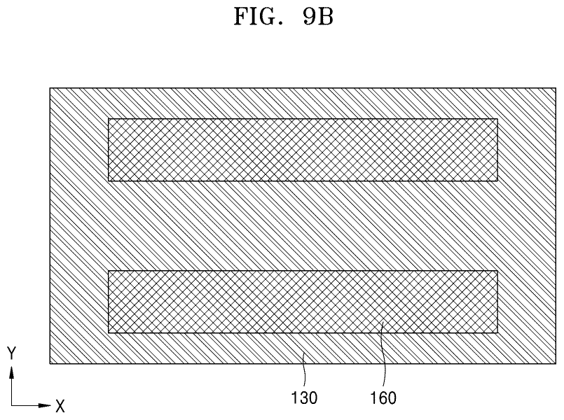

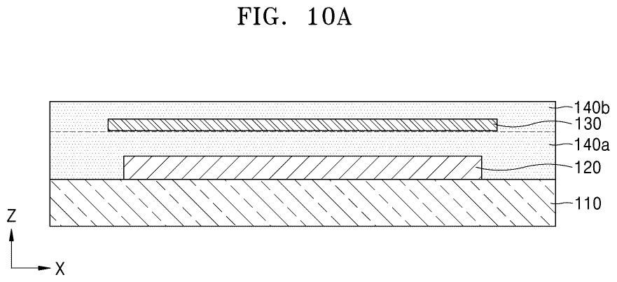

Referring to FIGS. 9A and 9B, a photoresist (PR) 160 may be provided on a channel layer 130. The PR 160 may serve to protect the channel layer 130 in the subsequent etching process. The PR 160 may be provided to overlap with a plurality of gate electrodes 120 in the z-axis direction. Through this, the channel layer 130 may be etched into the same shape as the plurality of gate electrodes 120.

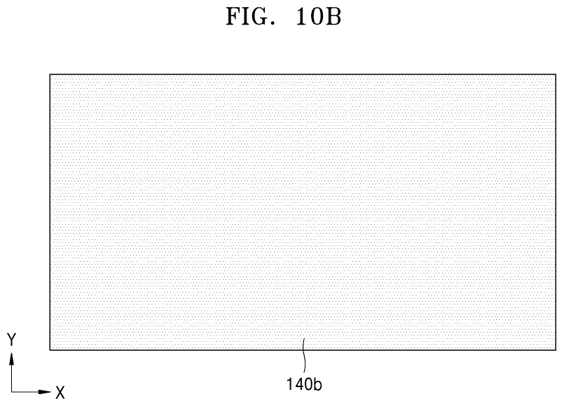

Referring to FIGS. 10A and 10B, after etching the channel layer 130, a second gate insulating layer 140b may be formed on the first gate insulating layer 140a. The second gate insulating layer 140b may be provided to surround the channel layer 130. The second gate insulating layer 140b may be formed by CVD, MOCVD or ALD processes.

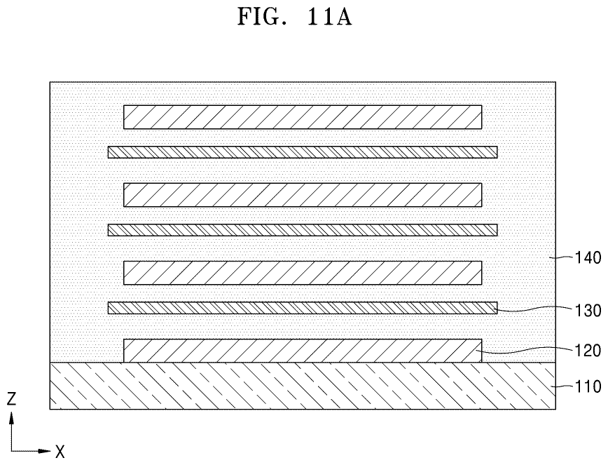

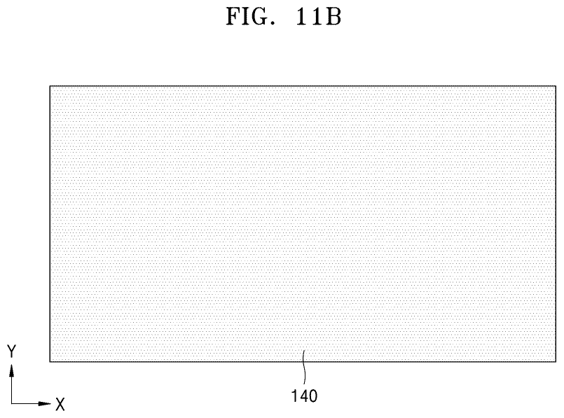

Referring to FIGS. 11A and 11B, by repeating the operations described with reference to FIGS. 6A to 10B, a stacked structure including the first gate stack GS1 of FIG. 4 and the second gate stack GS2 of FIG. 4 may be formed. The first gate stack GS1 of FIG. 4 and the second gate stack GS2 of FIG. 4 may have a structure that includes a channel layer 130 provided between the plurality of gate electrodes 120.

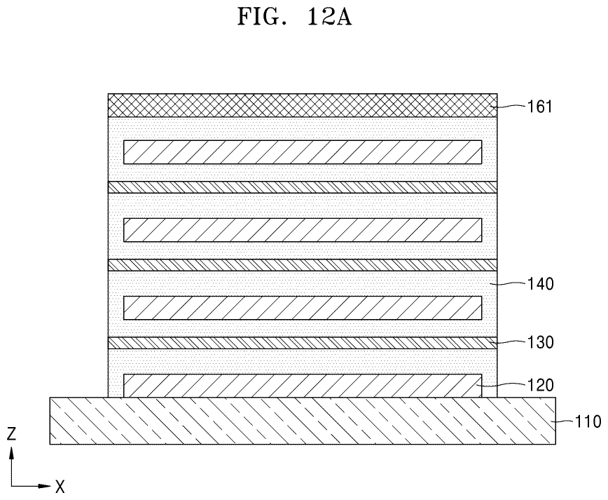

Referring to FIGS. 12A and 12B, a PR 161 may be provided on the gate insulating layer 140. The PR 161 may include a square-shaped hole 165 in the central part. The central part of the stacked structure may be etched through the PR 161 including a square-shaped hole 165. The gate insulating layer 140 at the central part of the stacked structure may be etched. The central part of the stacked structure may be etched to form a via (e.g., via hole) between the first gate stack GS1 in FIG. 4 and the second gate stack GS2 in FIG. 4.

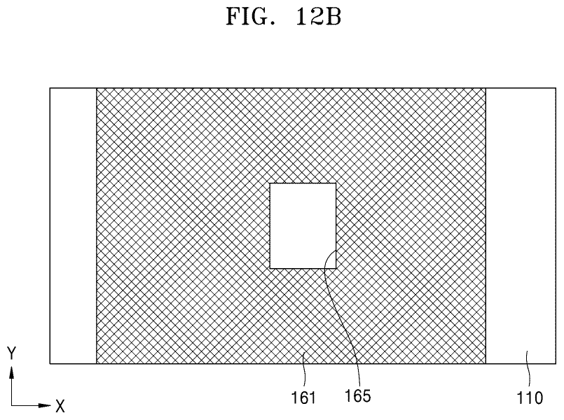

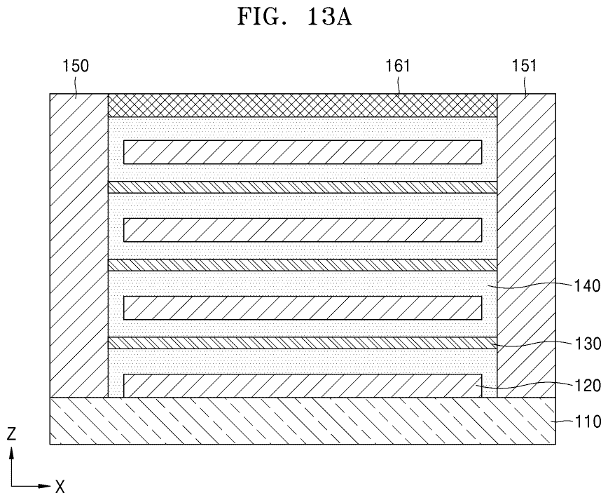

Referring to FIGS. 13A and 13B, a bridge 121 may be formed in the via of an etched stacked structure. The bridge 121 may be formed to connect the first gate stack GS1 of FIG. 1 and the second gate stack GS2 of FIG. 1. The bridge 121 may include, for example, TiN. A source electrode 150 and a drain electrode 151 may be formed at both edges of the substrate 110. The source electrode 150 and the drain electrode 151 may include, but are not limited to, highly electrically conductive metal materials such as Ag, Au, Pt, or Cu.

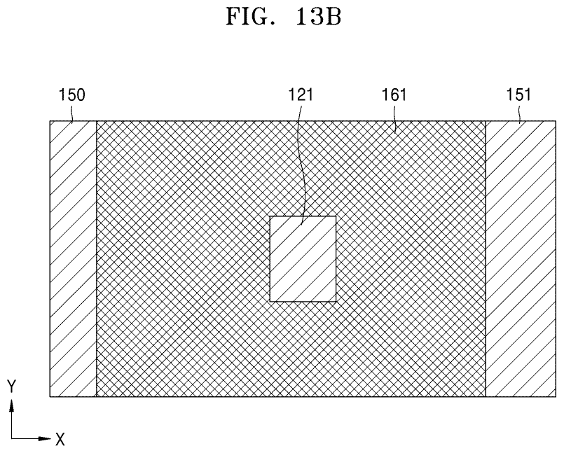

Referring to FIGS. 14A and 14B, the semiconductor device 100 of FIG. 1 may be formed by removing the PR 161. Through this process, it is possible to manufacture an MBCFET in which all channel layers 130 may have a GAA structure.

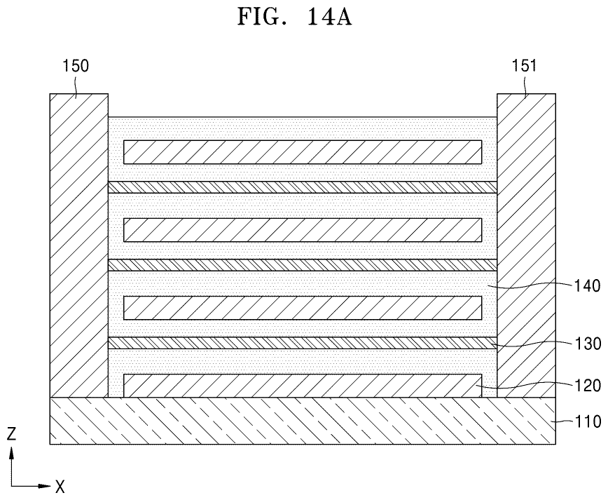

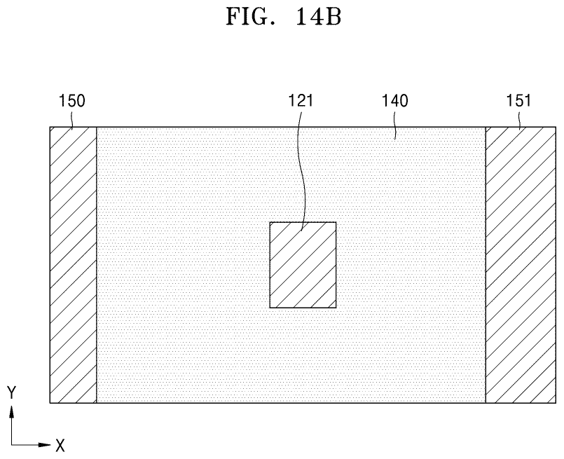

FIG. 15 is a schematic block diagram of a display driver integrated circuit (DDI) and a display device having the DDI according to an embodiment.

Referring to FIG. 15, the display device 220 may include a DDI 200, a main processing unit (MPU) 222, and a display panel 224. The DDI 200 may include a controller 202, a power supply circuit 204, a driver block 206, and a memory block 208. The controller 202 receives and decodes a command authorized from the MPU 222, and controls each block of the DDI 200 to implement an operation according to the command. The power supply circuit 204 generates a driving voltage in response to the control of the controller 202. The driver block 206 drives the display panel 224 using the driving voltage generated in the power supply circuit 204 in response to the control of the control unit 202. The display panel 224 may be a liquid crystal display panel or a plasma display panel. The memory block 208 is a block that temporarily stores commands input to the controller 202 or control signals output from the controller 202, or stores necessary data, and may include a memory such as RAM or ROM. The power supply circuitry 204 and the driver block 206 may include the semiconductor device according to the embodiments described above with reference to FIGS. 1 to 5.

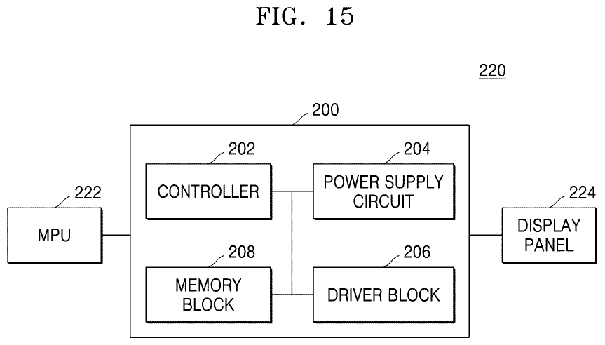

FIG. 16 is a block diagram of an electronic system including a semiconductor device according to an embodiment.

The electronic system 300 includes a memory 310 and a memory controller 320. The memory controller 320 may control the memory 310 for data reading from the memory 310 and/or data writing to the memory 310 in response to a request from a host 330. At least one of the memory 310 and the memory controller 320 may include the semiconductor device according to the embodiments described above with reference to FIGS. 1 to 5.

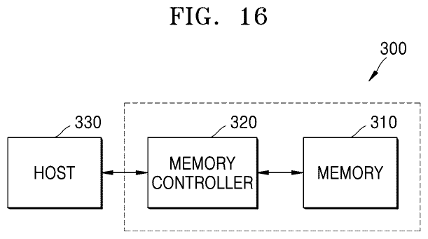

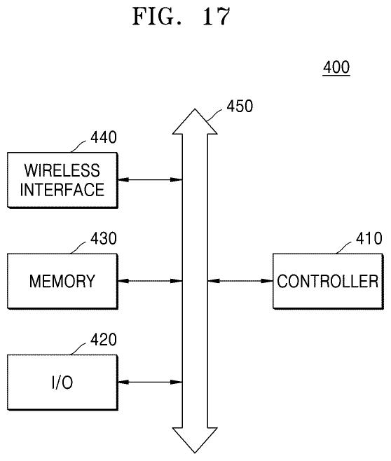

FIG. 17 is a block diagram of an electronic system including a semiconductor device according to an embodiment.

The electronic system 400 may constitute a wireless communication device, or a device capable of transmitting and/or receiving information in a wireless environment. The electronic system 400 includes a controller 410, an input/output device (I/O) 420, a memory 430, and a wireless interface 440, which are each interconnected via a bus 450.

The controller 410 may include at least one of a microprocessor, a digital signal processor, or a similar processing device. The input/output device 420 may include at least one of a keypad, a keyboard, or a display. The memory 430 may be used to store commands executed by the controller 410. For example, the memory 430 may be used to store user data. The electronic system 400 may use the wireless interface 440 to transmit/receive data via a wireless communication network. The wireless interface 440 may include an antenna and/or a wireless transceiver. In some embodiments, the electronic system 400 may be used for communication interface protocols of third-generation communication systems, such as code division multiple access (CDMA), global system for mobile communications (GSM), north American digital cellular (NADC), extended-time division multiple access (E-TDMA), and/or wide band code division multiple access (WCDMA). The electronic system 400 may include the semiconductor device according to the embodiments described above with reference to FIGS. 1 to 5.

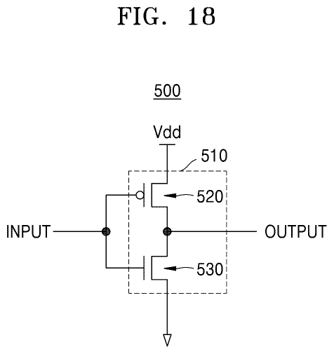

FIG. 18 is a circuit diagram of an inverter according to an embodiment.

Referring to FIG. 18, the inverter 500 includes a CMOS transistor 510. The CMOS transistor 510 includes a PMOS transistor 520 and an NMOS transistor 530 connected between a power terminal (Vdd) and a ground terminal. The CMOS transistor 510 may include a semiconductor device according to the embodiments described above with reference to FIGS. 1 to 5. The inverter 500 operates only one of the NMOSFET and PMOSFET depending on the input voltage, enabling a low-power circuit design.

According to the semiconductor device and the method for manufacturing the semiconductor device of the disclosure, a semiconductor device capable of applying an electric field to all surfaces of the channel layer may be provided by including a bridge connecting the first gate stack and the second gate stack. While the semiconductor devices and the semiconductor device manufacturing methods have been described with reference to the embodiments illustrated in the drawings, these are merely non-limiting examples, and it will be understood by those skilled in the art that various modifications and equivalent embodiments are possible therefrom. Therefore, the disclosed embodiments should be considered in an illustrative rather than a restrictive sense. The scope of the rights is defined by the claims, not in the foregoing disclosure, and all differences within an equivalent scope should be interpreted as being included in the scope of the rights.

According to the disclosure, a semiconductor device capable of applying an electric field to all surfaces of a TMD channel is provided.

According to the disclosure, a method of manufacturing a semiconductor device that limits and/or minimizes damage to the TMD channel during the process is provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first gate stack comprising a first channel layer and a plurality of first gate electrodes, the plurality of first gate electrodes being provided respectively on an upper portion of the first channel layer and a lower portion of the first channel layer;
a second gate stack comprising a second channel layer and a plurality of second gate electrodes, the plurality of second gate electrodes being provided respectively on an upper portion of the second channel layer and a lower portion of the second channel layer; and
a bridge connecting the first gate stack and the second gate stack.

2. The semiconductor device of claim 1, wherein the first gate stack and the second gate stack have a symmetric structure with respect to the bridge.

3. The semiconductor device of claim 1, wherein the first gate stack and the second gate stack do not have a symmetric structure with respect to the bridge.

4. The semiconductor device of claim 1, wherein the bridge connects the plurality of first gate electrodes and the plurality of second gate electrodes to each other.

5. The semiconductor device of claim 1, wherein the bridge comprises TiN.

6. The semiconductor device of claim 1, further comprising:
a source electrode on a first side of the first gate stack and the second gate stack, and
a drain electrode on a second side of the first gate stack and the second gate stack.

7. The semiconductor device of claim 1, further comprising:
a gate insulating layer, wherein
the gate insulating layer surrounds the first channel layer and the plurality of first gate electrodes, and
the gate insulating layer surrounds the second channel layer and the plurality of second gate electrodes.

8. The semiconductor device of claim 7, wherein the gate insulating layer comprises a high-k material.

9. The semiconductor device of claim 8, wherein the gate insulating layer comprises at least one of aluminum oxide, hafnium oxide, zirconium oxide, or lanthanum oxide.

10. The semiconductor device of claim 1, wherein the first channel layer and the second channel layer each independently comprise a transition metal dichalcogenide (TMD) material or an oxide semiconductor.

11. The semiconductor device of claim 10, wherein
at least one of the first channel layer and the second channel layer include the TMD material, and
the TMD material comprises at least one of MoS₂, WSe₂, MoSe₂, and WS₂.

12. The semiconductor device of claim 10, wherein
at least one of the first channel layer and the second channel layer include the oxide semiconductor, and
the oxide semiconductor includes indium-gallium-zinc oxide (IGZO) or indium tin oxide (ITO).

13. The semiconductor device of claim 1, wherein the plurality of first gate electrodes and the plurality of second gate electrodes comprise TiN.

14. The semiconductor device of claim 1, wherein the first gate stack and the second gate stack each independently are in an NMOS transistor or a PMOS transistor.

15. A method of manufacturing a semiconductor device comprising:
forming a first gate stack and a second gate stack on a substrate, the first gate stack including a first channel layer and a plurality of first gate electrodes provided respectively on an upper portion of the first channel layer and a lower portion of the first channel layer, and the second gate stack including a second channel layer and a plurality of second gate electrodes provided respectively on an upper portion of the second channel layer and a lower portion of the second channel layer;
forming a via between the first gate stack and the second gate stack; and
forming a bridge connecting the first gate stack and the second gate stack to the via.

16. The method of claim 15, wherein the first gate stack and the second gate stack are symmetric with respect to the bridge.

17. The method of claim 15, wherein the bridge connects the plurality of first gate electrodes and the plurality of second gate electrodes to each other.

18. The method of claim 15, wherein the bridge comprises TiN.

19. The method of claim 15, further comprising:
forming a gate insulating layer on the substrate, wherein
the gate insulating layer surrounds the first channel layer and the plurality of first gate electrodes, and
the gate insulating layer surrounds the second channel layer and the plurality of second gate electrodes.

20. The method of claim 15, wherein the first channel layer and the second channel layer each independently comprise a transition metal dichalcogenide (TMD) material or an oxide semiconductor.
